(19) United States
(12) Patent Application Publication
(10) Pub. No.: US 2009/0167369 A1
(43) Pub. Date: Jul. 2, 2009

(54) LVDS OUTPUT DRIVER

(75) Inventors: Shiue-Shin Liu, HsinChu City (TW); Tse-Hsiang Hsu, Hsin-Chu City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/146,723

(22) Filed: Jun. 26, 2008

Related U.S. Application Data
(60) Provisional application No. 61/017,187, filed on Dec. 28, 2007.

(51) Int. Cl. H03K 3/00

(52) U.S. Cl. 327/108

(57) ABSTRACT

An output driver is disclosed. The output driver has a pair of differential outputs coupled to a first supply voltage via a pair of load devices and comprises a current source, a pair of low voltage transistors, a pair of high voltage transistors, and a resistor. The current source has one end coupled to a second supply voltage. Each of the low voltage transistors has a first terminal coupled to the other end of the current source, a second terminal receiving a low voltage signal, and a third terminal. Each of the high voltage transistors has a first terminal coupled to the third terminal of a corresponding one of the low voltage transistors, a second terminal coupled to a bias voltage and a third terminal coupled to the output. The resistor is connected between the third terminals of the high voltage transistors.

### CROSS REFERENCE TO RELATED APPLICATIONS

This application claims the benefit of U.S. Provisional Application No. 61/017,187, filed on Dec. 28, 2007, the contents of which are incorporated herein by reference.

### BACKGROUND OF THE INVENTION

1. Field of the Invention

The invention relates to serial data transmission and, in particular, to an LVDS output driver.

2. Description of the Related Art

LVDS (low voltage differential signaling) is one of the specifications for high speed serial link. In LVDS, common mode voltage of output voltage is set to 1.125˜1.375 V. Accordingly, IO devices are required to implement an LVDS driver stage. A conventional configuration of an LVDS driver stage is an H-BOX circuit.

FIG. 1 is a circuit diagram of a conventional LVDS driver stage. In FIG. 1, the LVDS driver stage comprises a level shifter 110 and an H-box circuit 120. PMOS and NMOS transistors, which are IO devices generally operated by 3.3 Volt, are used to implement the H-BOX circuit 120. However, digital LVDS signals are usually generated by a digital core circuit with low power supply, for example, 1.2 Volt in 0.13 μm process technology. To drive the four MOS transistors in the H-BOX circuit 120, particularly the four IO devices, a level shifter 110 is required to shift a 1.2 Volt logic signal (i.e. the digital LVDS signal) to a 3.3 Volt logic signal. The level shifter 110 has several problems. First, a slew rate of the level shifter 110 is typically slow, especially in 1.08/3.6 Volt corner case. Second, a logic buffer 130 using 3.3 Volt IO devices, as shown in FIG. 1, suffers from lower driving capability compared with its core device counterpart. Accordingly, the logic buffer 130 of this type is not suitable for high speed operation. It is thus desirable to drive the H-BOX circuit directly with digital core logic buffers which are operating in lower voltage.

### BRIEF SUMMARY OF THE INVENTION

An embodiment of an output driver comprises a current source, a pair of low voltage transistors, a pair of high voltage transistors, and a resistor. The current source has one end coupled to a second supply voltage. Each of the low voltage transistors has a first terminal coupled to the other end of the current source, a second terminal receiving a low voltage signal, and a third terminal. Each of the high voltage transistors has a first terminal coupled to the third terminal of a corresponding one of the low voltage transistors, a second terminal coupled to a bias voltage, and a third terminal coupled to the output. The resistor is connected between the third terminals of the high voltage transistors. Differential outputs of the output driver are coupled to a first supply voltage via a pair of load devices.

An embodiment of an output driver comprises a pair of first transistors, a pair of second transistors, and a resistor. The second transistors are coupled to the differential serial link. The resistor is connected between drains of the second transistors. Threshold voltages of the first transistors are lower than threshold voltages of the second transistors. Each of the first transistors is cascoded-connected with a corresponding one of the second transistors.

An embodiment of an output driver comprises a pair of first transistors, a pair of second transistors, and a resistor. The second transistors are coupled to the differential serial link. The resistor is connected between drains of the second transistors. The first transistors are core devices and the second transistors are IO devices. Each of the first transistors is cascoded-connected with a corresponding one of the second transistors.

An embodiment of an output driver comprises a pair of first transistors, a pair of second transistors, and a resistor. The second transistors are coupled to the differential serial link. A gate of each of the second transistors is coupled to a bias voltage. The resistor is connected between drains of the second transistors. The first transistors are core devices and the second transistors are not core devices. Each of the first transistors is cascoded-connected with a corresponding one of the second transistors.

The invention provides an output driver whereby low voltage serial data is converted to a higher voltage without a level shifter. Thus, chip area and power consumption of the level shifter are eliminated. Meanwhile speed of the output driver is significantly improved.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a circuit diagram of a conventional LVDS driver stage; and

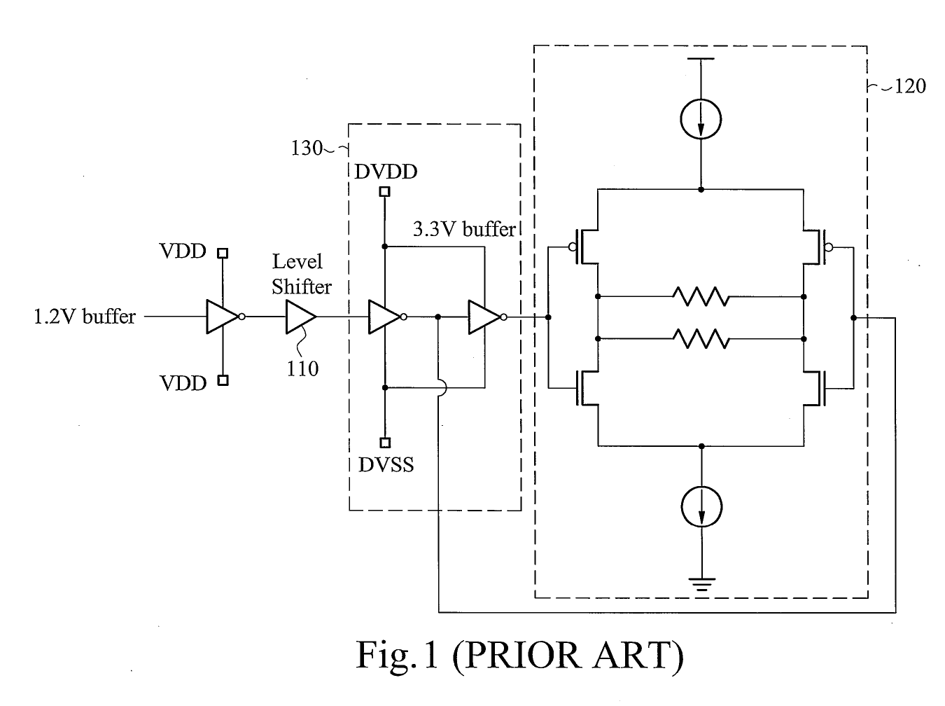

FIG. 2 is a circuit diagram of an output driver 200 according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

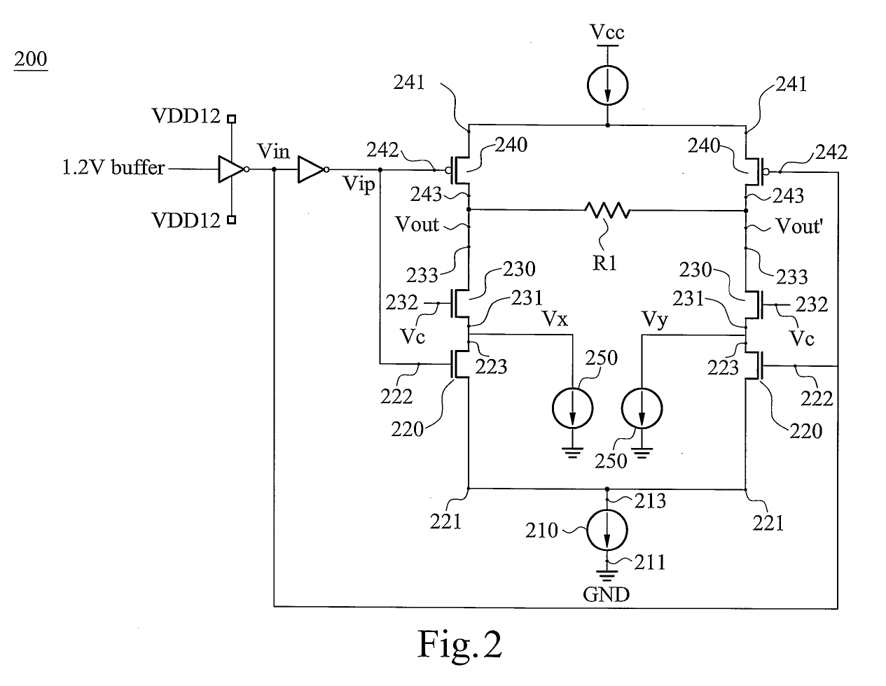

FIG. 2 is a circuit diagram of an output driver 200 according to an embodiment of the invention. A pair of differential outputs Vout and Vout′ of the output driver 200 is coupled to a first supply voltage via a pair of load devices 240. More specifically, the first supply voltage is a power voltage Vcc. The voltage value of Vcc depends on the requirement of the channel connected to the pair of differential outputs Vout and Vout′. Typically, the power voltage Vcc could be approximately 3 Volt in an LVDS output driver. In the embodiment, the load devices are high voltage PMOS transistors 240, which are namely IO devices utilized in IC chips. Each of the PMOS transistors 240 has a source 241 coupled to the first supply voltage Vcc via a current source, a gate 242 controlled by a low voltage data signal Vip/Vin, and a drain 243. The output driver 200 comprises a current source 210, a pair of low voltage transistor 220, a pair of high voltage transistors 230, and local load resistor R1. In some applications, the load resistor R1 may locate only at receiver end and does not appear inside output driver. The current source 210 has one end 211 coupled to a second supply voltage. More specifically, the second supply voltage is a signal ground GND. Each of the low voltage transistors 220 has a first terminal 221 coupled to the other end 213 of the current source 210, a second terminal 222 receiving a low voltage data signal Vip/Vin, and a third terminal 223. Each of the high voltage transistors 230 has a first terminal 231 coupled to the third terminal 223 of a corresponding one of the low voltage transistors 220, a second terminal 232 coupled to a bias voltage Vc, and a third terminal 233 coupled to the differential outputs Vout and Vout′ of the output driver 200. The load resistor R1 is coupled between the drains 233 of the high voltage transistors 230. The low voltage transistors 220 and high voltage transistors 230 are NMOS transistors. The first, second, and third terminals thereof are respectively sources, gates, and drains. In addition, the bias voltage is provided from a bias generation circuit. In another embodiment, the transistor 230 need not be a high voltage device, for example, can be implemented by namely a core device 10 devices utilized in IC chips. At least one low voltage transistors can be cascoded-connected to the transistor 220 to make sure that there are no reliability issues when common mode of Vout and Vout′ is in a proper voltage range (for example, 1.125 to 1.375 Volt in the embodiment of FIG. 2). The channel is, for example, a differential serial link. The differential serial link is, for example, an LVDS interface.

In FIG. 2, each of the high voltage transistors 230 is cascoded-connected with a corresponding one of the low voltage transistors 220 to protect the low voltage transistors 220 from high voltage stress. The high voltage transistors 230 are biased at the bias voltage such that the high voltage transistors 230 operate in a saturation region when turned on. In addition, the circuit can be designed to keep voltages Vx and Vy sustained by the low voltage transistors 220 such that the low voltage transistors 220 are not damaged by overly high voltage. Threshold voltages of the low voltage transistors 220, 0.3 Volt in 0.13 μm CMOS technology for example, is low and the low voltage transistors 220 can be directly driven by the low voltage data signal Vip and Vin, with a high state of 1 Volt for example. In such a way, driving low-speed high-voltage transistors with such high speed data signal can be avoided. One advantage of using the output driver 200 is that no high voltage (3.3 Volt in this embodiment) signal is needed to be inputted into the driver because both load device 240 and low voltage transistors 220 can be directly driven by low voltage data. In recent developments, digital circuitry has employed core devices to for higher speeds and smaller chip areas. A core device usually requires a lower operation voltage than a common standard or traditional device. However, the output of a digital circuit sometimes has to drive a relatively high voltage interface, such as the serial link mentioned above.

Referring to FIG. 2, when the gates of the PMOS transistors 240 on the left and right branch of the output driver 200 respectively receive a differential signal of 1.2 Volt (Vip) and 0 Volt (Vin) and the low voltage NMOS transistors 220 on the left and right branch of the output driver 200 respectively receive a differential signal of 1.2 Volt (Vip) and 0 Volt (Vin), the PMOS transistor 240 on the right branch and the low voltage transistor 220 on the left branch are turned on and the PMOS transistor 240 on the left branch and the low voltage transistor 220 on the right branch are turned off. As a result, current flows through the PMOS transistor 240 on the right branch, the resistor R1 and the low voltage transistor 220 on the left branch. The output signal Vout′ on the right branch is thus pulled up, for example, to 1.43 Volt and the output signal Vout on the left branch is pulled down, for example, to 1.07 Volt. To the contrary, when the differential signal is driven in a state complementary to the previously mentioned state, the differential output signal is also reversed.

In addition, in some embodiments, the output driver 200 further comprises a pair of current sources 250 each coupled to the third terminal of a corresponding one of the low voltage transistors 220. The current sources 250, whose current amount may not need to be large, are used to pull nodes Vx/Vy. Since cascoded NMOS transistors 230 are operated in a saturation region, the node nodes Vx/Vy are pulled under 1.2 Volt efficiently by a small current, 100 μA for example. Otherwise, the nodes Vx/Vy will be charged to a high level (in this case 1.43 Volt) of LVDS specification and there will be a reliability problem.

The invention provides an output driver whereby low voltage serial data is converted to a higher voltage without a level shifter. Thus, chip area and power consumption of the level shifter are eliminated. Meanwhile speed of the output driver is significantly improved.

While the invention has been described by way of example and in terms of preferred embodiment, it is to be understood that the invention is not limited thereto. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An output driver having a pair of differential outputs coupled to a first supply voltage via a pair of load devices, comprising:
a current source having one end coupled to a second supply voltage;
a pair of low voltage transistors each having a first terminal coupled to the other end of the current source, a second terminal for receiving one of a pair of low voltage signals, and a third terminal;
a pair of high voltage transistors each having a first terminal coupled to the third terminal of a corresponding one of the pair of low voltage transistors, a second terminal coupled to a bias voltage, and a third terminal coupled to a corresponding one of the pair of differential outputs; and
a resistor connected between the third terminals of the pair of high voltage transistors.

2. The output driver as claimed in claim 1, wherein the second supply voltage is a signal ground.

3. The output driver as claimed in claim 1, wherein the pair of high voltage transistors and the pair of low voltage transistors are NMOS transistors.

4. The output driver as claimed in claim 1, further comprising a pair of current sources each coupled between the third terminal of a corresponding one of the low voltage transistors and a signal ground.

5. The output driver as claimed in claim 1, wherein the pair of load devices are high voltage transistors coupled to the differential outputs.

6. An output driver for driving a differential serial link, the output driver comprising:
a pair of first transistors;
a pair of second transistors coupled to the differential serial link; and
a resistor connected between drains of the second transistors,
wherein threshold voltages of the first transistors are lower than threshold voltages of the second transistors, and each of the first transistors is cascoded-connected with a corresponding one of the second transistors.

7. The output driver as claimed in claim 6, wherein the differential serial link is an LVDS interface.

8. The output driver as claimed in claim 6, further comprising a pair of current sources each coupled to the source of a corresponding one of the second transistors.

9. An output driver for driving a differential serial link, the output driver comprising:
a pair of first transistors;
a pair of second transistors coupled to the differential serial link; and
a resistor connected between drains of the second transistors,
wherein the first transistors are core devices and the second transistors are IO devices, and each of the first transistors is cascoded-connected with a corresponding one of the second transistors.

10. The output driver as claimed in claim 9, wherein the differential serial link is a low voltage differential signaling (LVDS) interface.

11. The output driver as claimed in claim 10, further comprising a pair of current sources each coupled between the source of a corresponding one of the second transistors and a signal ground.

12. An output driver for driving a differential serial link, the output driver comprising:
a pair of first transistors;
a pair of second transistors coupled to the differential serial link, and a gate of each of the second transistors being coupled to a bias voltage; and
a resistor connected between drains of the second transistors,
wherein each of the first transistors is cascoded-connected with a corresponding one of the second transistors.

13. The output driver as claimed in claim 12, wherein the differential serial link is a low voltage differential signaling (LVDS) interface.

14. The output driver as claimed in claim 13, further comprising a pair of current sources each coupled between the source of a corresponding one of the second transistors and a signal ground.

15. An output driver having a pair of differential outputs, comprising:
a first pair of high voltage transistors each having a first terminal, a second terminal coupled to a bias voltage, and a third terminal coupled to a corresponding one of the pair of differential outputs;
a resistor connected between the third terminals of the first pair of high voltage transistors;
a second pair of high voltage transistors each coupled between the resistor and a first supply voltage; and
a pair of low voltage transistors each having a first terminal coupled to a second supply voltage, a second terminal for receiving one of a pair of low voltage signals, and a third terminal coupled to the first terminal of a corresponding one of the first pair of high voltage transistors.

16. The output driver as claimed in claim 15, wherein the second supply voltage is a signal ground.

17. The output driver as claimed in claim 15, wherein the first pair of high voltage transistors and the pair of low voltage transistors are NMOS transistors and the second pair of high voltage transistors are PMOS transistors.

18. The output driver as claimed in claim 15, further comprising a pair of current sources each coupled between the third terminal of a corresponding one of the low voltage transistors and a signal ground.
